(19) United States
(12) Patent Application Publication
(10) Pub. No.: US 2014/0355180 A1
(43) Pub. Date: Dec. 4, 2014

(54) ELECTRONIC DEVICE HAVING CABLE POSITIONING MECHANSIM

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventor: XIAO-HUI ZHOU, Shenzhen (CN)

(73) Assignees: HON HAI PRECISION INDUSTRY CO., LTD., New Taipei (TW); HONG FU JIN PRECISION INDSUTRY (ShenZhen) CO., LTD., Shenzhen (CN)

(21) Appl. No.: 14/029,882

(22) Filed: Sep. 18, 2013

(30) Foreign Application Priority Data
May 31, 2013 (CN) 2013203064059

(51) Int. Cl. H05K 7/00

(52) U.S. Cl. CPC H05K 7/00
USPC 361/679.01

(57) ABSTRACT

An electronic device, includes a housing, at least one cable received in the housing, and at least one cable positioning mechanism secured to the housing for fastening the cable. The cable position mechanism defines a receiving portion for receiving the cable. The receiving portion further receives glue to fasten the cable.

### BACKGROUND

1. Technical Field

The present disclosure relates to an electronic device for fastening an electric cable utilizing cable positioning mechanism.

2. Description of Related Art

Most electronic devices always includes a plurality of cables for electrically connecting internal components. However, most of the time, the cables in the electronic device are arranged randomly. Thus, when maintaining or serving or repairing the electronic device, time is wasted in trying to figure out which cable goes where.

Therefore, there is room for improvement in the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the three views.

FIG. 1 is a partial perspective view of an electronic device in accordance with an embodiment; the electronic device includes two cable positioning mechanisms.

FIG. 2 is a perspective view showing the cable positioning mechanisms of FIG. 1 fastening a cable.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

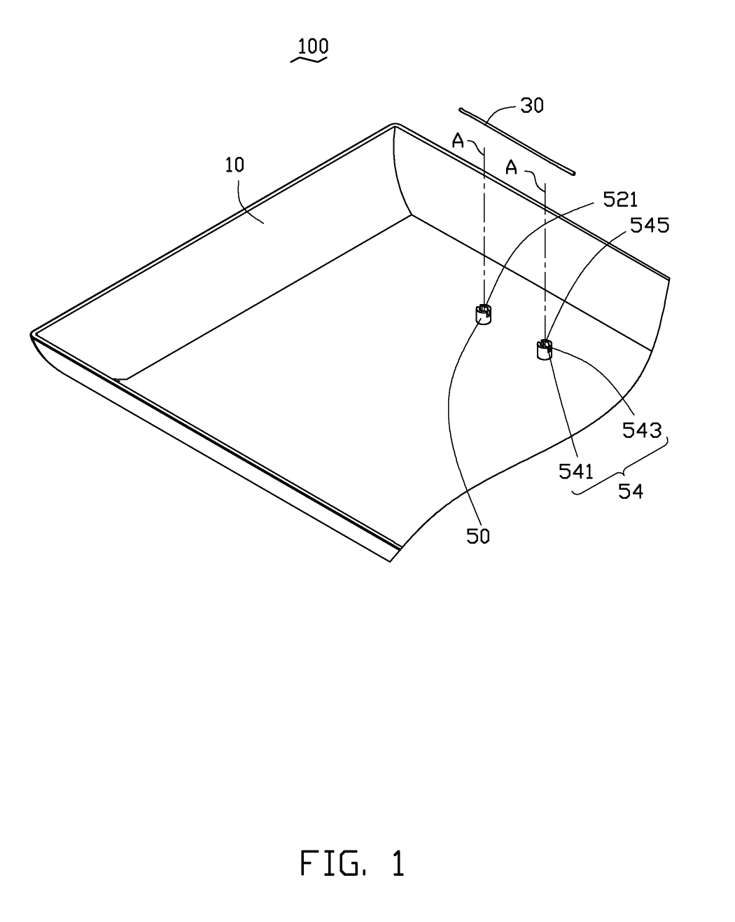

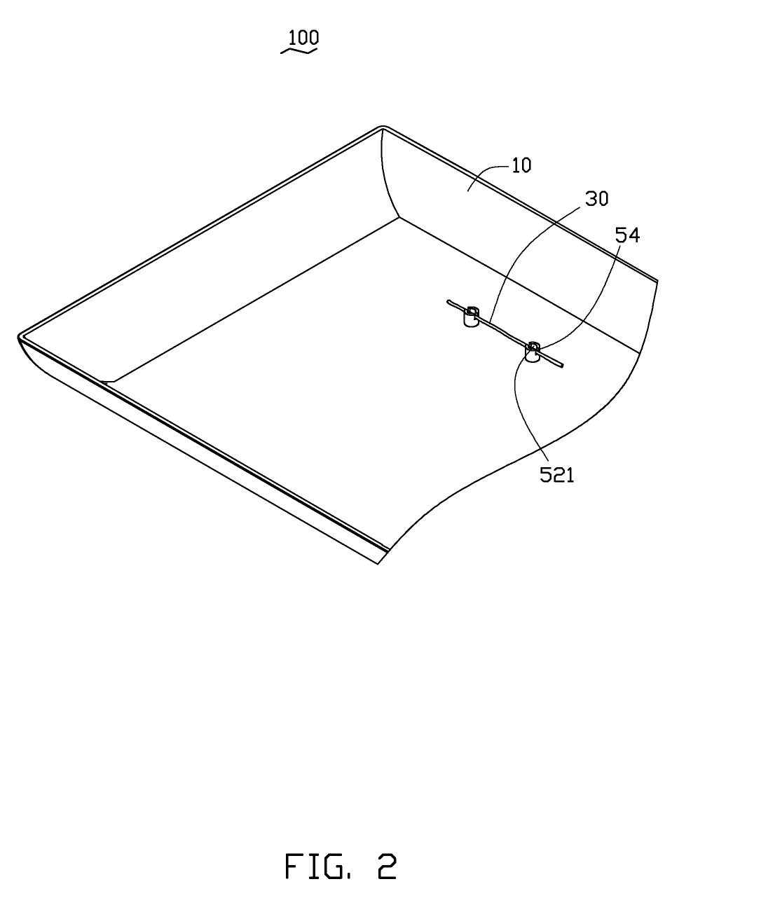

FIGS. 1-2 show an electronic device 100 in accordance with an embodiment. The electronic device 100 includes a housing 10, a cable 30, and two cable positioning mechanisms 50 for fastening the cable 30 to the housing 10. The electronic device 100 may be a notebook computer, a digital versatile disc (DVD) player, a mobile phone, for example. The electronic device 100 in the embodiment is a DVD player.

The cable positioning mechanisms 50 are secured to an inner surface of the housing 10 and spaced apart from each other. Each cable positioning mechanism 50 is substantially cylindrical, and protrudes from the inner surface of the housing 10. Each cable positioning mechanism 50 has an axis A. An end of each cable positioning mechanism 50 away from the inner surface of the housing 10 recesses to define a receiving portion 521. The receiving portion 521 extends along axially (namely, along the axis A). The diameter of the receiving portion 521 is greater than the diameter of the cable 30, and the depth of the receiving portion 521 in the axis A is also greater than the diameter of the cable 30. An end of each cable positioning mechanism 50 away from the inner surface of the housing 10 further defines two clamping slits 54 communicating with the receiving portion 521. The clamping slits 54 are substantially U shaped, and are adapted to clamp the cable 30. The clamping slits 54 are arranged symmetrically relative to the axis A. Each clamping slits 54 includes a bottom wall 541 adjacent to the inner surface of the housing 10 and two sidewalls 543 extending from opposite ends of the bottom wall 541. The two sidewalls 543 are parallel to and spaced apart from each other. The distance between the sidewalls 543 is slightly less than the diameter of the cable 30, to allow the cable 30 to be fitted into the clamping slits 54. In other embodiments, the shape and position of the clamping slits 54 may be changed according to requirements, for example, the two clamping slits 54 are arranged unsymmetrical relative to the axis A, whereby the cable 30 clamped therebetween is curved.

FIG. 2 shows that in use, the first step is to clamp the cable 30 between the clamping slits 54 of one of the cable positioning mechanisms 50. Then, the cable 30 is straightened and is further clamped between the clamping slits 54 of the other cable positioning mechanism 50. Finally, glue is dispense on the receiving portion 521 for further adhering the cable 30 to the cable positioning mechanisms 50. As a result, the cable 203 is steadily fastened to the housing 10 by the cable positioning mechanisms 50. Because both the diameter of the receiving portion 521 and the depth of the receiving portion 521 in the axis A are also greater than the diameter of the cable 30, thus, an overabundance of glue will flow into the receiving portion 521.

It is to be understood, even though information and advantages of the present embodiments have been set forth in the foregoing description, together with details of the structures and functions of the present embodiments, the disclosure is illustrative only; and that changes may be made in detail, especially in matters of shape, size, and arrangement of parts within the principles of the present embodiments to the full extent indicated by the broad general meaning of the terms in which the appended claims are expressed.

What is claimed is:

1. An electronic device, comprising:
a housing;
at least one cable received in the housing; and
at least one cable positioning mechanism secured to the housing for fastening the at least one cable;
wherein the at least one cable position mechanism defines a receiving portion for receiving the at least one cable, the receiving portion further receives glue therein to adhere the at least one cable.

2. The electronic device of claim 1, wherein the at least one cable positioning mechanism is cylindrical and protrudes from an inner surface of the housing, the receiving portion extends along an axis of the at least one cable positioning mechanism.

3. The electronic device of claim 2, wherein an end of the at least one cable positioning mechanism away from the inner surface of the housing defines two clamping slits for clamping at least one cable therebetween.

4. The electronic device of claim 3, wherein the clamping slits communicate with the receiving portion, and are arranged symmetrically relative to the axis of at least one cable positioning mechanism.

5. The electronic device of claim 2, wherein each clamping slit comprises a bottom wall adjacent to the inner surface of the housing and two sidewalls extending from opposite ends of the bottom wall and parallel to each other.

6. The electronic device of claim 5, wherein the distance between the sidewalls is slightly less than the diameter of the at least one cable.

7. The electronic device of claim 1, wherein the diameter of the receiving portion is greater than the diameter of the at least one cable.
